(19) United States
(12) Patent Application Publication
(10) Pub. No.: US 2025/0151399 A1
(43) Pub. Date: May 8, 2025

(54) MANUFACTURING METHOD FOR ARRAY SUBSTRATE, ARRAY SUBSTRATE AND DISPLAY APPARATUS

(71) Applicant: BOE Technology Group Co., Ltd., Beijing (CN)

(72) Inventors: Zhijun LV, Beijing (CN); Qi YAO, Beijing (CN); Feng ZHANG, Beijing (CN); Wenqu LIU, Beijing (CN); Liwen DONG, Beijing (CN); Zhao CUI, Beijing (CN); Detian MENG, Beijing (CN); Dongfei HOU, Beijing (CN); Yuqiao LI, Beijing (CN); Jiaxiang ZHANG, Beijing (CN); Jingshang ZHOU, Beijing (CN)

(73) Assignee: BOE Technology Group Co., Ltd., Beijing (CN)

(21) Appl. No.: 19/017,830

(22) Filed: Jan. 13, 2025

Related U.S. Application Data
(63) Continuation of application No. PCT/CN2023/078932, filed on Mar. 1, 2023.

(51) Int. Cl. H10D 86/40; H01L 25/075; H10D 86/01

(52) U.S. Cl. CPC H10D 86/443; H01L 25/0753; H10D 86/0221

(57) ABSTRACT

A manufacturing method for an array substrate, an array substrate, and a display apparatus. The manufacturing method comprises: step S100, providing a base substrate; step S200, forming a driving circuit layer on one side of the base substrate the driving circuit layer comprising a plurality of wires and a plurality of bonding pads; step S300, forming a removable protective layer on the side of the driving circuit layer away from the base substrate; and step S400, connecting functional devices to the bonding pads, the removable protective layer being decomposed and removed in step S400. Between step S200 and step S300, there are no steps of forming an inorganic protective layer and patterning the inorganic protective layer.

### CROSS-REFERENCE TO RELATED APPLICATION

This disclosure is a U.S. Continuation Application of International Application No. PCT/CN2023/078932, filed on Mar. 1, 2023, entitled “Manufacturing Method for Array Substrate, Array Substrate and Display Apparatus”, the content of which is incorporated by reference herein in its entirety.

### TECHNICAL FIELD

The present disclosure relates to the field of display technology, and particularly, to a manufacturing method for an array substrate, an array substrate, and a display apparatus.

### BACKGROUND

A mini LED backlight, as the latest liquid crystal (LCD) backlight technology, can fully meet the needs of a high-end consumer market with the help of rapid development of the LED industry. In the related art, the cost for manufacturing the mini LED backlight is high, which limits the development of LCD +mini LED backlight in the display field.

The information disclosed in the Background is only used to enhance understanding of the background of the present disclosure, and therefore it may include information that does not constitute existing technology already known to those ordinary skilled in the art.

### SUMMARY

An objective of the present disclosure is to provide a manufacturing method for an array substrate, an array substrate, and a display apparatus to simplify processing and reduce production cost.

To achieve the above objective, the present disclosure employs following technical solutions.

According to a first aspect of the present disclosure, it is provided with a manufacturing method for an array substrate, including:

providing a base substrate;

forming a drive circuit layer on a side of the base substrate, the drive circuit layer comprising a plurality of wirings and a plurality of pads, and the plurality of wirings and the plurality of pads being disposed on a same layer;

forming a removable protective layer on a side of the drive circuit layer away from the base substrate, an orthographic projection of the removable protective layer on the base substrate at least partially overlapping with orthographic projections of the plurality of wirings and the plurality of pads on the base substrate; and

connecting a functional device to the pads, the removable protective layer being decomposed and removed in this step,

wherein a step of forming an inorganic protective layer and patterning the inorganic protective layer is not be included between a step of forming the drive circuit layer on the side of the base substrate and a step of forming the removable protective layer on the side of the drive circuit layer away from the base substrate.

In an exemplary embodiment of the present disclosure, forming the drive circuit layer on the side of the base substrate includes:

forming a conductive seed layer on the side of the base substrate;

forming a removable pattern defining layer on a surface of the conductive seed layer away from the base substrate, the removable pattern defining layer being provided with a plurality of first openings, and the first openings exposing a part of the conductive seed layer;

forming an electroplated metal layer on the surface of the conductive seed layer in the first openings by an electroplating process, the electroplated metal layer comprising a plurality of growth wirings and a plurality of growth pads;

removing the removable pattern defining layer; and

removing a part of the conductive seed layer, which is not covered by the electroplated metal layer, to form a plurality of seed wirings and a plurality of seed pads, the seed wirings and the growth wirings in correspondence with the seed wirings forming the wirings, and the seed pads and the growth pads in correspondence with the seed pads forming the pads,

forming the removable protective layer on the side of the drive circuit layer away from the base substrate includes:

forming the removable protective layer on a side of the electroplated metal layer away from the base substrate.

In an exemplary embodiment of the present disclosure, forming the removable pattern defining layer on the surface of the conductive seed layer away from the base substrate includes: forming a photoresist material layer on the surface of the conductive seed layer away from the base substrate; and

exposing and developing the photoresist material layer to form the removable pattern defining layer.

In an exemplary embodiment of the present disclosure, the photoresist material layer is formed by using a degradable photoresist material, and the degradable photoresist material is a material capable of being dissolved in a degradation solution after curing; and

removing the removable pattern defining layer includes:

dissolving the removable pattern defining layer by using the degradation solution.

In an exemplary embodiment of the present disclosure, the photoresist material layer is a positive photoresist material layer; and

an angle between a sidewall of each of the first openings and a plane where the electroplated metal layer is located is from 75° to 90 °.

In an exemplary embodiment of the present disclosure, the base substrate includes a plurality of sub-electroplated regions arranged in an array, and each of the sub-electroplated regions comprises a first electroplated region and a second electroplated region;

forming the electroplated metal layer on the surface of the conductive seed layer in the first openings by the electroplating process includes:

by the electroplating process, forming a first electroplated metal layer on the surface of the conductive seed layer in the first openings located in the first electroplated region, and forming a second electroplated metal layer on the surface of the conductive seed layer in the first openings located in the second electroplated region,

wherein the first electroplated metal layer comprises the plurality of growth wirings and the plurality of growth pads, the second electroplated metal layer comprises a virtual growth wiring, and the electroplated metal layer comprises the first electroplated metal layer and the second electroplated metal layer.

In an exemplary embodiment of the present disclosure, the first electroplated region is located at a periphery of the second electroplated region.

In an exemplary embodiment of the present disclosure, a ratio of an area of the electroplated metal layer to an area of the array substrate does not exceed ⅓.

In an exemplary embodiment of the present disclosure, a thickness of the removable pattern defining layer is greater than a thickness of the electroplated metal layer; and the thickness of the removable pattern defining layer is from 8 μm to 20 μm.

In an exemplary embodiment of the present disclosure, forming the removable protective layer on the side of the electroplated metal layer away from the base substrate includes:

micro-etching a surface of the electroplated metal layer away from the base substrate; and

forming the removable protective layer on the surface of the electroplated metal layer away from the base substrate.

In an exemplary embodiment of the present disclosure, after forming the removable protective layer on the side of the electroplated metal layer away from the base substrate and before connecting the functional device to the pads, the manufacturing method further includes:

forming a solder resist layer on a surface of the removable protective layer away from the base substrate, the solder resist layer having a plurality of second openings, and an orthographic projection of the second openings on the base substrate at least partially overlapping with an orthographic projection of the pads on the base substrate.

In an exemplary embodiment of the present disclosure, after removing the part of the conductive seed layer, which is not covered by the electroplated metal layer, and before forming the removable protective layer on the side of the electroplated metal layer away from the base substrate, the manufacturing method further includes:

forming a solder resist layer on a surface of the electroplated metal layer away from the base substrate, the solder resist layer having a plurality of second openings, and the second openings exposing at least a portion (i.e., partial region) of the pads.

In an exemplary embodiment of the present disclosure, forming the removable protective layer on the side of the electroplated metal layer away from the base substrate includes:

forming the removable protective layer by a film forming process, the removable protective layer at least covering the surface of the electroplated metal layer exposed by the solder resist layer.

In an exemplary embodiment of the present disclosure, the wiring and the pad have a thickness of 4 μm-18 μm.

According to a second aspect of the present disclosure, it is provided with an array substrate manufactured by the manufacturing method according to any one of the first aspect.

According to a third aspect of the present disclosure, it is provided with a display apparatus, including the array substrate according to the second aspect.

In the manufacturing method for the array substrate according to the present disclosure, the drive circuit layer formed includes the plurality of wirings and the plurality of pads, and the plurality of wirings and the plurality of pads are disposed on the same layer. This method allows the wirings and the pads to be formed at the same time without need to be formed in separate layers, which can greatly shorten the production time and reduce the production cost. In addition, the present disclosure omits the process step of forming the inorganic protective layer on the surface of the drive circuit layer and patterning the inorganic protective layer, which can help to improve the growth efficiency and reduce the production cost.

### BRIEF DESCRIPTION OF THE DRAWINGS

The above and other features and advantages of the present disclosure will become more apparent by describing in detail exemplary implementations thereof with reference to the accompanying drawings.

FIG. 1 is a structural schematic view of an array substrate according to an exemplary embodiment of the present disclosure;

FIG. 2 is a flowchart of a manufacturing method for an array substrate according to an exemplary embodiment of the present disclosure;

FIG. 3 is another flowchart of a manufacturing method for an array substrate according to an exemplary embodiment of the present disclosure;

FIG. 4 is a structural schematic view of forming a conductive seed layer according to an exemplary embodiment of the present disclosure;

FIG. 5 is a structural schematic view of forming a removable pattern defining layer according to an exemplary embodiment of the present disclosure;

FIG. 6 is a structural schematic view of forming an electroplated metal layer according to an exemplary embodiment of the present disclosure;

FIG. 7 is a structural schematic view of removing a removable pattern defining layer according to an exemplary embodiment of the present disclosure;

FIG. 8 is a structural schematic view after removing a part of a conductive seed layer according to an exemplary embodiment of the present disclosure;

FIG. 9 is a structural schematic view of forming a removable protective layer according to an exemplary embodiment of the present disclosure;

FIG. 10 is a structural schematic view of forming a removable protective layer according to another exemplary embodiment of the present disclosure;

FIG. 11 is a plan view of an array substrate according to an exemplary embodiment of the present disclosure;

FIG. 12 is a schematic view of a lighting structure for an array substrate according to an exemplary embodiment of the present disclosure;

FIG. 13 is a schematic view of a lighting structure for an array substrate according to an exemplary embodiment of the present disclosure.

### REFERENCE NUMBERS OF PRIMARY COMPONENTS ARE PROVIDED AS FOLLOWS

100-base substrate; 110-sub-electroplated region; 111-first electroplated region; 112-second electroplated region; 200-buffer layer; 301-conductive seed layer; 302-removable pattern defining layer; 021-first opening; 303-electroplated metal layer; 304-wiring; 041-seed wiring; 042-growth wiring; 305-pad; 051-seed pad; 052-growth pad; 400-removable protective layer;

500-solder resist layer; 601-LED; 602-flexible circuit board or drive chip; 001-virtual growth wiring.

### DETAILED DESCRIPTION

Now, the exemplary embodiments will be described more fully with reference to the accompanying drawings. However, the exemplary embodiments can be embodied in a variety of forms and should not be construed as limiting the embodiments set forth herein. Instead, these embodiments are provided so that the present disclosure will be thorough and complete, and the concepts of the exemplary embodiments will be fully given to those skilled in the art. The features, structures or characteristics described herein may be combined in one or more embodiments in any suitable manner. In the following description, numerous specific details are provided to fully understand the embodiments of the present disclosure.

In drawings, thicknesses of regions and layers may be exaggerated for sake of clarity. Same reference numbers denote the same or similar structures in the figures, and thus the detailed description thereof will be omitted.

The features, structures or characteristics described herein may be combined in one or more embodiments in any suitable manner. In the following description, numerous specific details are provided to fully understand the embodiments of the present disclosure. However, those skilled in the art will recognize that the technical solutions of the present disclosure may be practiced without one or more of the specific details, or other methods, components, materials may be used. Under other circumstances, well-known structures, materials or operations will not be illustrated or described in detail, to avoid obscuring main technical creation of the present disclosure.

When a structure is described as “above” another structure, it probably means that the structure is integrally formed on another structure, or, the structure is “directly” disposed on another structure, or, the structure is “indirectly” disposed on another structure through a further structure.

Words such as “one,” “an/a” and “said” are used herein to indicate the presence of one or more elements/components/etc. Terms “include” and “have” are used to indicate an inclusive meaning and refer to the possibility of the existence of additional elements/components/etc. in addition to those as listed. Terms “first,” “second” and “third” are used herein only as markers but not limit the number of objects.

A mini LED backlight, as a liquid crystal (LCD) backlight technology, can fully meet the needs of the high-end consumer market with the help of rapid development of the LED industry. Its main advantages lie in that mini LED backlight packaging can use flip-chip Mini LED chips to achieve uniform light mixing directly, without the need for a lens for secondary optical design. Due to the small structure of the chips themselves, it is beneficial to make the local dimming zones more detailed, thus achieving a higher dynamic range (HDR) and realizing a higher contrast effect. On the other hand, it can also shorten the optical mixing distance (OD) to reduce the overall thickness of the device, achieving an ultra-thin design. The mini LED backlight can be combined with local dimming technology to control on-off and brightness adjustment of the corresponding backlight areas in real-time according to the brightness and darkness of the picture in the display signal, making the blacker blacks, the whiter whites, and the colors more naturally vibrant. The visual realism can bring an immersive, best-in-class experience.

In the related art, when manufacturing structures such as wirings and pads, the mini-LED backlight usually adopts different conductive layers to form wirings and pads respectively, and the wirings and the pads need to be connected through transfer wires. This method is complex and costly. In the related art, it is also necessary to form an inorganic protective layer on a surface of a wiring layer and pattern the inorganic protective layer to expose a die bonding sites, etc., which further increases production cost.

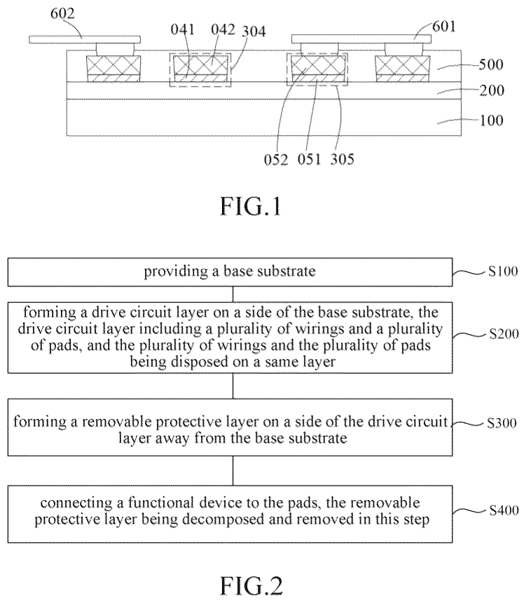

As shown in FIG. 1 and FIG. 2, the present disclosure provides a manufacturing method for an array substrate, including:

step S100, providing a base substrate 100;

step S200, forming a drive circuit layer on a side of the base substrate 100, the drive circuit layer including a plurality of wirings 304 and a plurality of pads 305, and the plurality of wirings 304 and the plurality of pads 305 being disposed in a same layer;

step S300, forming a removable protective layer 400 on a side of the drive circuit layer away from the base substrate 100, an orthographic projection of the removable protective layer 400 on the base substrate 100 at least partially overlapping with orthographic projections of the plurality of wirings 304 and the plurality of pads 305 on the base substrate 100;

step S400, connecting a functional device to the pads 305, the removable protective layer 400 being decomposed and removed in this step;

wherein a step of forming an inorganic protective layer and patterning the inorganic protective layer may not be included between the step of forming the drive circuit layer on the side of the base substrate 100 and the step of forming the removable protective layer 400 on the side of the drive circuit layer away from the base substrate 100.

In the manufacturing method for the array substrate according to the present disclosure, the drive circuit layer formed includes the plurality of wirings 304 and the plurality of pads 305, and the plurality of wirings 304 and the plurality of pads 305 are disposed in the same layer. This method allows the wirings 304 and the pads 305 to be formed at the same time without need to be formed in separate layers, which can greatly shorten the production time and reduce the production cost. In addition, the present disclosure omits the process step of forming the inorganic protective layer on a surface of the drive circuit layer and patterning the inorganic protective layer, which helps to improve the growth efficiency and reduce the production cost.

Steps of the manufacturing method for the array substrate according to the present disclosure will be described in detail below with reference to the accompanying drawings.

The array substrate according to the present disclosure may be used as a backlight source of an LCD display apparatus or may be used as a passively driven display panel, which is not particularly limited in the present disclosure.

As shown in FIG. 2 and FIG. 4, in step S100, the base substrate 100 is provided.

In some embodiments of the present disclosure, the base substrate 100 may be a base substrate 100 of inorganic material or a base substrate 100 of organic material. For example, in an embodiment of the present disclosure, a material of the base substrate 100 may be a glass material such as soda-lime glass, quartz glass and sapphire glass, or may be a metal material such as stainless steel, aluminum and nickel. In another embodiment of the present disclosure, the material of the base substrate 100 may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN), or a combination thereof. In another embodiment of the present disclosure, the base substrate 100 may also be a flexible base substrate 100, for example, the material of the base substrate 100 may be polyimide (PI). The base substrate 100 may also be a composite of multiple layers of materials, for example, in an embodiment of the present disclosure, the base substrate 100 may include a bottom film layer, a pressure-sensitive adhesive layer, a first polyimide layer and a second polyimide layer which are sequentially laminated. Preferably, the base substrate 100 is a glass substrate.

In step S200, the drive circuit layer is formed on the side of the base substrate 100. For example, the drive circuit layer includes a passive drive circuit, for example, the drive circuit layer includes a drive circuit composed of the plurality of wirings 304 and the plurality of pads 305.

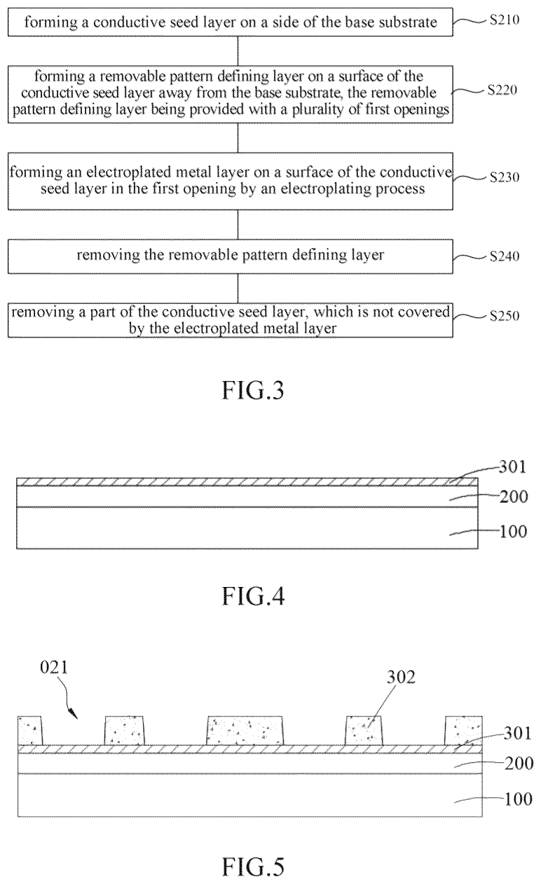

As shown in FIG. 3 and FIGS. 4-8, in some embodiments, step S200 includes: step S210, as shown in FIG. 4, forming a conductive seed layer 301 on the side of the base substrate 100;

step S220, as shown in FIG. 5, forming a removable pattern defining layer 302 on a surface of the conductive seed layer 301 away from the base substrate 100, the removable pattern defining layer 302 being provided with a plurality of first openings 021, and the first openings 021 exposing part of the conductive seed layer 301;

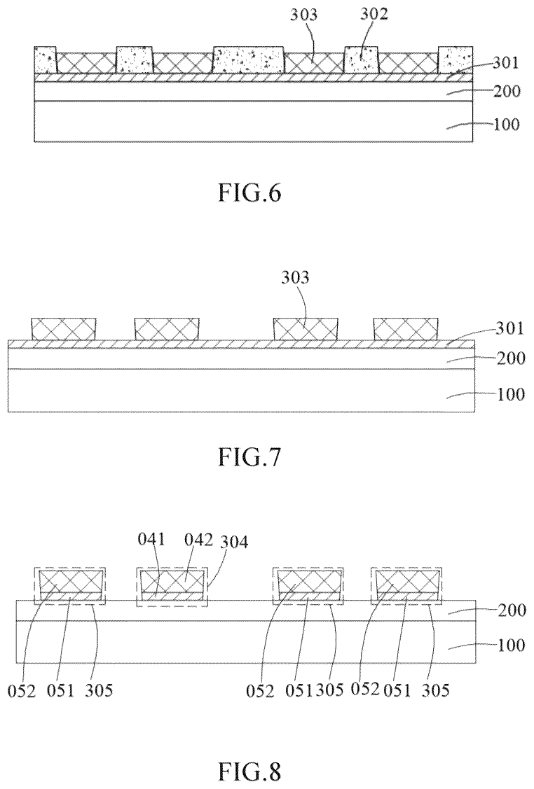

step S230, as shown in FIG. 6, forming an electroplated metal layer 303 on the surface of the conductive seed layer 301 in the first openings 021 by an electroplating process, the electroplated metal layer 303 including a plurality of growth wirings 042 and a plurality of growth pads 052;

step S240, as shown in FIG. 7, removing the removable pattern defining layer 302; step S250, as shown in FIG. 8, removing a part of the conductive seed layer 301, which is not covered by the electroplated metal layer 303, to form a plurality of seed wirings 041 and a plurality of seed pads 051, the seed wirings 041 and the corresponding growth wirings 042 forming the wirings 304, and the seed pads 051 and the corresponding growth pads 052 forming the pads 305.

In the related art, when a structure such as a wiring and a pad is manufactured, a whole seed layer is formed on the base substrate, and then a copper growth layer is grown on the seed layer by the electroplating process, so that the copper growth layer is electroplated on the whole surface. In order to avoid excessive stress on the substrate, this method cannot form a copper growth layer with a greater thickness, and since the copper growth layer formed by electroplating on the whole surface has a large area, the required growth time is long, and the production cost is high.

In the manufacturing method for the array substrate according to the present disclosure, the removable pattern defining layer 302 is formed on the surface of the conductive seed layer 301 away from the base substrate 100, the removable pattern defining layer 302 has the plurality of first openings 021, and the first openings 021 expose part of the conductive seed layer 301. The electroplated metal layer 303 is formed by electroplating in the first openings 021, so that the electroplated metal layer 303 formed has a small area, which helps to reduce the electroplating time and the production cost. Furthermore, the electroplated metal layer 303 formed in the first openings 021 is a patterned electroplated metal layer 303, so that the electroplated metal layer 303 does not need to be patterned and etched, which helps to reduce the etching time and further lowers the production cost. In addition, the removable pattern defining layer 302 helps to form a thicker electroplated metal layer 303 by electroplating, and such a structure provides a basis for omitting subsequent process steps of forming an inorganic protective layer on a surface of the electroplated metal layer 303 and etching the inorganic protective layer, which further helps to reduce the production cost.

In the present disclosure, the wirings 304 contained in the drive circuit layer may include a seed wiring 041 and a growth wiring 042 laminated on a surface of the seed wiring 041 away from the base substrate 100. The pads 305 may include a seed pad 051 and a growth pad 052 laminated on a surface of the seed pad 051 away from the base substrate 100. Further, in some embodiments, all wirings 304 and all pads 305 included in the drive circuit are formed by the conductive seed layer 301 and the same electroplated metal layer 303.

In step S210, the conductive seed layer 301 is formed on the side of the base substrate 100.

In some embodiments of the present disclosure, a metal material may be deposited on the side of the base substrate 100 to form the conductive seed layer 301. For example, a metal material may be deposited on one side of the base substrate 100 by a magnetron sputtering method, to form the conductive seed layer 301 as an electroplated base. It can be understood that an intermediate substrate may be obtained according to the process steps that have been performed, before depositing the metal material. Depending on different process steps that have been performed, the intermediate substrate may have different structures, for example, may be the base substrate 100 per se, or may include the base substrate 100 as well as various film layers that have been formed and sequentially laminated on the base substrate 100. In step S210, the metal material may be deposited on a surface of the intermediate substrate on which the conductive seed layer 301 is to be formed.

For example, in an embodiment of the present disclosure, before forming the conductive seed layer 301, the method further includes:

step S110, as shown in FIG. 6, forming a buffer layer 200 on the side of the base substrate 100. In this embodiment, the base substrate 100 and the buffer layer 200 as a whole may serve as the intermediate substrate. The buffer layer 200 may be made of an insulating material. The buffer layer 200 helps to improve warpage of the base substrate 100 and improve uniformity and integrity of the subsequent conductive seed layer 301. The buffer layer 200 may have a thickness of 3000 Å to 4000 Å, for example, 3500 Å, and will not be specifically limited.

As shown in FIG. 4, in step S210, the thickness of the conductive seed layer 301 formed may be not greater than 1 μm, to avoid excessive stress on the intermediate substrate caused by an excessively thick conductive seed layer 301, and enhance the stability and yield of the array substrate. Preferably, the thickness of the conductive seed layer 301 may be not greater than 0.5 μm, to shorten the etching time of the conductive seed layer 301 in step S250 and improve a side profile of the seed wirings 041 formed after the etching.

The conductive seed layer 301 may be made of a metal material, or may be made of an alloy formed by a plurality of metal materials, or may be made of a plurality of metal layers laminated, which will not particularly limited in the present disclosure, as long as electroplating requirements and performance requirements of the array substrate are satisfied.

Optionally, the conductive seed layer 301 may include a protective metal layer and a target metal layer on a surface of the protective metal layer away from the base substrate 100. The target metal layer may serve as an electroplated base, and the electroplated metal layer 303 is formed on a surface of the target metal layer away from the base substrate 100. For example, when the electroplating process is a copper plating process, the material of the target metal layer may be a copper.

The protective metal layer is configured to protect the target metal layer from erosion, or protect the intermediate substrate from erosion by the metal material of the target metal layer. The protective metal layer may be made of a metal element or an alloy, for example, molybdenum, titanium, molybdenum-titanium-nickel alloy, or the like.

In an embodiment of the present disclosure, the conductive seed layer 301 includes the protective metal layer and the target metal layer sequentially laminated on a side of the base substrate 100. The material of the protective metal layer may be an MTD alloy (molybdenum-titanium-nickel alloy) with a thickness of 250 Å-350 Å; and the material of the target metal layer is a copper with a thickness of 2500 Å-3500 Å.

As shown in FIG. 5, in step S220, the removable pattern defining layer 302 is formed on the surface of the conductive seed layer 301 away from the base substrate 100, the removable pattern defining layer 302 is provided with the plurality of first openings 021, and the first openings 021 expose part of the conductive seed layer 301.

In this step, during the electroplating process, the conductive seed layer 301 exposed by the first openings 021 may be used as an electroplated base to grow an electroplated metal, while the conductive seed layer 301 covered by the removable pattern defining layer 302 cannot grow the electroplated metal. Therefore, orthographic projections of the first openings 021 on the base substrate 100 may overlap with an orthographic projection of the electroplated metal layer 303 formed in step S230.

In some embodiments of the present disclosure, the removable pattern defining layer 302 may be manufactured by step S221 and step S222.

In step S221, a photoresist material layer is formed on the surface of the conductive seed layer 301 away from the base substrate 100.

In step S222, the photoresist material layer is exposed and developed to form the removable pattern defining layer 302.

In an embodiment of the present disclosure, in step S221, the photoresist material layer may be formed on the surface of the conductive seed layer 301 away from the base substrate 100 by using a degradable photoresist material. The degradable photoresist material is a photoresist material that can be dissolved in a degradation solution after curing.

Optionally, the degradable photoresist material has decomposable crosslinking groups or forms decomposable crosslinking groups during the curing. After the degradable photoresist material is cured, when the cured degradable photoresist material needs to be removed, the cured degradable photoresist material may be treated by using a degradation solution, and the decomposable crosslinking groups in the cured degradable photoresist material may react with the degradation solution to be broken, so that the cured degradable photoresist material is decomposed into small molecular fragments that may be dissolved in the degradation solution. In this way, the cured degradable photoresist material can be gently and thoroughly removed.

In step S221, the photoresist material layer is made by using the degradable photoresist material, and the material of the removable pattern defining layer 302 made in step S222 is the cured degradable photoresist material. In step S240, the removable pattern defining layer 302 may be dissolved by using the degradation solution, to remove the removable pattern defining layer 302. This can ensure thorough removal of the removable pattern defining layer 302, but also avoid damage to the electroplated metal layer 303 when the removable pattern defining layer 302 is removed.

In another embodiment of the present disclosure, in step S221, a positive photoresist material is used to form the photoresist material layer, that is, the photoresist material layer is a positive photoresist material layer. In step S222, an angle between a sidewall of the first opening 021 of the removable pattern defining layer 302 and a plane where the electroplated metal layer 303 is located is from 75° to 90°, specifically may be 75°, 78°, 80°, 82°, 84°, 86°, 88°, 89° or 90°, but is not limited thereto. In this way, when the wiring 304 is manufactured and formed, a difference between a width of one end, close to the base substrate 100, of the growth wiring 042 in the wiring 304 and a width of another end, away from the base substrate 100, of the growth wiring 042 is not too large. This structure can ensure continuity of subsequent formation of a film layer on a surface of the electroplated metal layer 303 away from the base substrate 100.

A thickness of the removable pattern defining layer may be adjusted according to a thickness of the electroplated metal layer 303 to be formed. The thickness of the removable pattern defining layer is greater than the thickness of the electroplated metal layer 303 to be formed. In an embodiment, the thickness of the removable pattern defining layer is from 8 μm to 20 μm, specifically may be 8 μm, 9 μm, 10 μm, 11 μm, 12 μm, 13 μm, 14 μm, 15 μm, 16 μm, 17 μm, 18 μm, or 20 μm, but is not limited thereto. Within this range, a thinner or thicker electroplated metal layer 303 may be formed to meet different plating requirements. In particular, the electroplated metal layer 303 with a greater thickness may be formed, so that it can be ensured that pressure different of the subsequently formed wirings 304 may not be too great, to meet the application requirements.

However, in the related art, after the conductive seed layer 301 is formed in a whole layer, the electroplated metal layer 303 is formed in a whole layer by electroplating on the surface of the conductive seed layer 301. Due to the whole layer structure, the electroplated metal layer 303 is limited by the stress on the base substrate 100 caused by the electroplated metal layer 303, and it is impossible to form an electroplated metal layer 303 with a greater thickness in the related art, resulting in that the subsequently formed wirings 304 has a relatively great pressure difference, and thereby affecting the effect of use.

As shown in FIG. 6 and FIG. 8, in step S230, the electroplated metal layer 303 is formed on the surface of the conductive seed layer 301 in the first openings 021 by the electroplating process, and the electroplated metal layer 303 includes the plurality of growth wirings 042 and the plurality of growth pads 052.

In the electroplating process, the electroplated metal grows from the surface of the conductive seed layer 301 serving as the electroplated base; under the constraint of the first openings 021, the electroplated metal only grows in the first openings 021 and eventually forms growth wirings 042 and growth pads 052 located in the first openings 021 after electroplating; and the growth wirings 042 and the growth pads 052 form the electroplated metal layer 303.

Since the conductive seed layer 301 is a whole metal surface, an electroplating current may be conveniently applied to the whole conductive seed layer 301 and thus the conductive seed layer 301 may have a very small voltage drop, which can improve the uniformity of the electroplating rate at each of the first openings 021, and hence improve the uniformity of surfaces of the growth wirings 042 and the growth pads 052 away from the base substrate 100.

Optionally, the thickness of the electroplated metal layer 303 may be controlled by controlling parameters of the electroplating process, such as the electroplating current and the electroplating time. Optionally, in step S230, the thickness of the electroplated metal layer 303 may be not greater than five times a width of the first opening 021. In other words, a minimum value of the width of the first opening 021 is a first size value, i.e., a minimum value of a width of the growth wiring 042 or the growth pad 052 is the first size value; the thickness of the electroplated metal layer 303 is a second size value, i.e., a thickness of the growth wiring 042 or the growth pad 052 is the second size value; and the second size value is not greater than five times the first size value. As a result, an aspect ratio of the growth wiring 042 or the growth pad 052 prepared is not greater than 5, which can improve bonding strength among the growth wiring 042, the growth pad 052 and the conductive seed layer 301, and prevent the growth wiring 042 and the growth pad 052 from collapsing, thereby improving the stability of the growth wiring 042.

Optionally, the thickness of the electroplated metal layer 303 is not less than 4 μm, and may be 4 μm-18 μm, which, for example, specifically may be 4 μm, 5 μm, 6 μm, 7 μm, 8 μm, 9 μm, 10 μm, 11 μm, 12 μm, 13 μm, 14 μm, 15 μm, 16 μm, 17 >m or 18 μm, but is not limited thereto. Preferably, the thickness of the electroplated metal layer 303 is from 5 μm to 10 μm.

Optionally, a copper electroplating process may be adopted, so that the material of the electroplated metal layer 303 is a copper. In this way, a resistance of the growth wiring 042 can be reduced, and thus the resistance of the wiring 304 can be reduced. Further, the surface of the conductive seed layer 301 away from the base substrate 100 includes at least one copper metal layer, which can ensure a copper-electroplated metal layer 303 can smoothly grow on the surface of the conductive seed layer 301 in the electroplating process.

Compared with the related art, the present disclosure only needs to form the electroplated metal layer 303 in a partial region, i.e., in the first openings 021, during electroplating. In the related art, electroplating is performed on the whole layer, i.e., the electroplated metal layer 303 is formed in the whole region. That is, an area of the electroplated metal layer 303 to be formed in the present disclosure is much smaller than an area of the electroplated metal layer 303 to be formed in the related art. Thus, the electroplating time can be shortened, the production efficiency can be improved, and the production cost can be reduced.

Preferably, a ratio of the area of the electroplated metal layer 303 to an area of the array substrate does not exceed ⅓.

In some embodiments, the uniformity of the thickness of the electroplated metal layer 303 may be improved by step S231.

As shown in FIG. 11, the base substrate 100 includes a plurality of sub-electroplated regions 110 arranged in an array, and each of the sub-electroplated regions 110 includes a first electroplated region 111 and a second electroplated region 112.

In step S231, a first electroplated metal layer on the surface of the conductive seed layer 301 is formed in the first openings 021 in the first electroplated region 111, and a second electroplated metal layer on the surface of the conductive seed layer 301 is formed in the first openings 021 in the second electroplated region 112, by the electroplating process.

The first electroplated metal layer includes the plurality of growth wirings 042 and the plurality of growth pads 052, the second electroplated metal layer includes a virtual growth wiring 001, and the electroplated metal layer 303 includes the first electroplated metal layer and the second electroplated metal layer.

In step S231, the first openings 021 may be partially located in the first electroplated region 111 and partially located in the second electroplated region 112. The second electroplated region 112 may be an auxiliary plating region for assisting in adjusting the uniformity of the thickness of the electroplated metal layer 303. The specific division of the second electroplated region 112 and the first electroplated region 111 may be adjusted according to an actually required drive circuit. For example, in an embodiment, the wirings 304 and the pads 305 in the drive circuit to be formed in each sub-electroplated region 110 are located at positions close to an outer edge of the region, and correspondingly the first electroplated region 111 is located at a periphery of the second electroplated region 112, so that the uniformity of the electric field distribution of the sub-electroplated region 110 during electroplating can be adjusted, thereby adjusting the uniformity of the thickness of the electroplated metal layer 303 formed by electroplating.

It should be noted that the first opening 021 located in the first electroplated region 111 may have a same shape as or a different shape from the first opening 021 in the second electroplated region 112, which is not specifically limited. Specifically, the shape of the first opening 021 in the first electroplated region 111 may be set according to a pattern of the wirings 304 and the pads 305 to be formed, while the shape of the first opening 021 in the second electroplated region 112 may be various, for example, a projection of the first opening 021 on the base substrate 100 may be a straight line, a curved line, an “L” shape or an irregular shape, which is not specifically limited.

During electroplating, the first electroplated metal layer on the surface of the conductive seed layer 301 is formed in the first openings 021 in the first electroplated region 111, and the second electroplated metal layer on the surface of the conductive seed layer 301 is formed in the first openings 021 in the second electroplated region 112. The first electroplated metal layer includes the plurality of growth wirings 042 and the plurality of growth pads 052. The second electroplated metal layer includes the virtual growth wiring 001. The virtual growth wiring 001 may not provide any signals, but only assist in adjusting the uniformity of the electroplated metal layer 303, or rather may be understood as adjusting the uniformity of the thickness of the plurality of wirings 304 or the plurality of pads 305.

As shown in FIG. 8, in step S250, the part of the conductive seed layer 301, which is not covered by the electroplated metal layer 303, is removed.

The part of the conductive seed layer 301, which is not covered by the electroplated metal layer 303, may be removed by etching. Optionally, a suitable etching process may be selected according to the thickness and material of the conductive seed layer 301, including selection of a suitable etching solution, etching time and the like, so that an exposed part of the conductive seed layer 301 can be etched completely.

When etching the conductive seed layer 301, there is no need to specially protect the electroplated metal layer 303. As a result, the surfaces of the growth wirings 042 and the growth pads 052 of the electroplated metal layer 303 are partially etched in the etching process, and the remaining part, together with the seed wirings 041 or the seed pads 051, forms the corresponding wirings 304 or pads 305. In some embodiments, the electroplated metal layer 303 and the conductive seed layer 301 may be etched at a close rate, so that the thickness of the formed wirings 304 is close to the thickness of the electroplated metal layer 303. For example, if the thickness of the electroplated metal layer 303 is 4 μm-18 μm, the thickness of the formed wirings 304 is 4 μm-18 μm. Certainly, in this step, the electroplated metal layer 303 and the conductive metal layer may also be etched with different etching parameters. For example, in a region of the growth wirings 042 and in a region of the growth pads 052, etching parameters of the two regions are different, so that a thickness of the etched growth wirings 042 is different from a thickness of the etched growth pads 052. For example, the thickness of the etched growth wirings 042 is less than the thickness of the etched growth pads 052.

In some embodiments, before etching, a surface of the growth wiring 042 and the growth pad 052 away from the base substrate 100 have a slightly rough surface, and a protruding part of the surface is more easily etched by the etching solution, so that flatness of the surface of the growth wirings 042 away from the base substrate 100 before etching is continuously improved in the etching process. Furthermore, since the electroplated metal layer 303 does not need protection, in the formed wiring 304, an orthographic projection of the growth wiring 042 on the base substrate 100 overlaps with an orthographic projection of the seed wiring 041 on the base substrate 100, which can ensure flatness of a side surface of the wiring 304 and avoid a problem that a sidewall of the seed wiring 041 protrudes from a sidewall of the growth wiring 042. Hence, the surface and the side surface of the wiring 304 have higher flatness, which can further improve the profile of the wiring 304 and enhance the performance of the array substrate.

Compared with the related art, the etching process in the present disclosure takes the conductive seed layer 301 as an etching object, but the etching object in the related art has two layers, i.e., the electroplated metal layer 303 and the conductive seed layer 301. That is, the thickness of the etching object in the present disclosure is much smaller than the thickness of the etching object in the related art. As a result, the etching time can be greatly shortened, thereby improving the production efficiency and reducing the production cost.

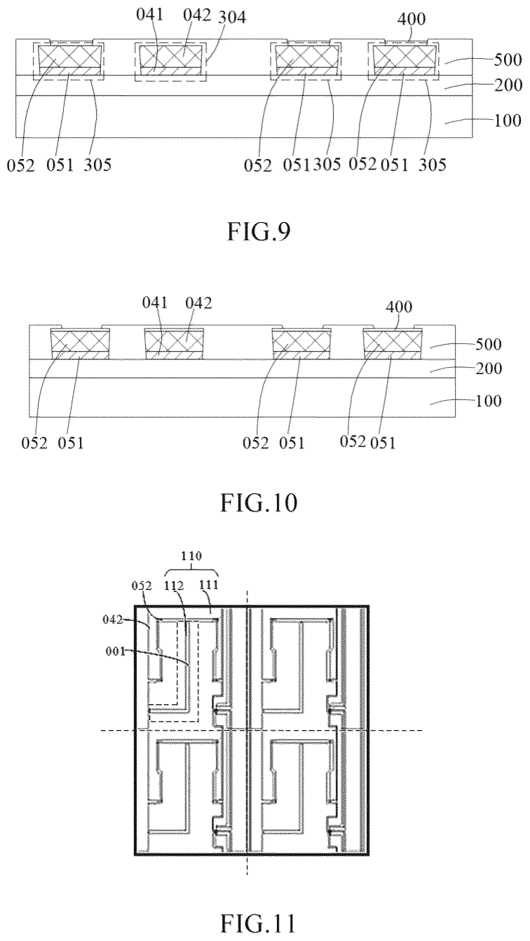

As shown in FIG. 9, FIG. 10 and FIG. 1, in step S300 to step S400, the surface of the electroplated metal layer 303 is protected, and the functional device is connected to the pads 305 to form an array substrate having a light-emitting function.

The functional device may include a flexible circuit board or drive chip 602 and a LED 601. The LED 601 may be an LED light bead, or may be a micro LED or a mini LED. Taking the LED 601 as an example, each sub-electroplated region 110 may be connected with a plurality of LEDs 601. For example, as shown in FIG. 11, each sub-electroplated region 110 of the array substrate has at least eight pads 305; every two pads 305 are connected to one LED 601, i.e., one of the two pads 305 is connected to one electrode of the LED 601, and the other of the two pads 305 is connected to the other electrode of the LED 601. Different LEDs 601 may be connected in series or in parallel with each other through the wiring 304 to form a light-emitting unit. Each light-emitting unit may be loaded with a common voltage or a drive voltage through different wirings 304, to drive the LEDs 601 to emit light.

In step S300, a removable protective layer 400 is formed on the side of the drive circuit layer away from the base substrate 100, and the orthographic projection of the removable protective layer 400 on the base substrate 100 at least partially overlaps with the orthographic projections of the plurality of wirings 304 and the plurality of pads 305 on the base substrate 100.

The removable protective layer may be formed through step S310.

As shown in FIG. 9 and FIG. 10, in step S310, the removable protective layer 400 is formed on a side of the electroplated metal layer 303 away from the base substrate 100.

In step S310, the removable protective layer 400 is formed on the side of the electroplated metal layer 303 away from the base substrate 100, and the orthographic projection of the electroplated metal layer 303 on the base substrate 100 at least partially overlaps with the orthographic projection of the removable protective layer 400 on the base substrate 100.

The removable protective layer 400 may be an organic solderability preservative (OSP), which has oxidation resistance, thermal shock resistance and moisture resistance, and is configured to protect the surface of the electroplated metal layer 303 from further oxidation in a normal environment. The removable protective layer 400 must be easily removed by a flux at a subsequent high soldering temperature, so that an exposed clean copper surface can be immediately combined with a molten solder in an extremely short time to form a firm solder joint.

In some embodiments of the present disclosure, the material of the removable protective layer 400 may be selected from rosin, active resin, and aromatics. In a case where the electroplated metal layer 303 is for example a copper layer, an active component substituted for an imidazole (1,3-diazaphole) derivative may be used to chemically react with a surface of the metal copper, which may form a homogeneous, extremely thin, transparent organic coating layer at a soldering site. The excellent heat resistance forms a coordination bond between a copper atom and N on an organic compound ring, to constitute a stable complex that continuously extends and complexes. The copper atom is continuously complexed with an organic compound molecule, so that an organic copper coordination polymer film is formed on a surface of the bare copper. The complexation and cross-linking reaction between an organic compound and bivalent copper ions under certain conditions, as well as hydrogen bonds and Van der Waals forces existing between directly linked groups of the organic compound allow the OSP to selectively form a thin film of the complex on the clean copper surface, which can protect the copper from being oxidized and corroded in the soldering process.

In the present disclosure, the removable protective layer 400 may be formed on the surface of the electroplated metal layer 303 away from the base substrate 100, or the removable protective layer 400 may be formed on a surface of a solder resist layer 500 away from the base substrate 100 after a film layer such as the solder resist layer 500 is formed on the surface of the electroplated metal layer 303 away from the base substrate 100. It should be noted that, in the manufacturing method for the array substrate according to the present disclosure, no inorganic protective layer is provided between the electroplated metal layer 303 and the removable protective layer 400. The removable protective layer 400 formed may have a thickness in a range of 1000 Å-3000 Å, such as 2000 Å.

As shown in FIG. 10, in an embodiment, a removable protective material layer is directly formed on a surface of the electroplated metal layer 303 away from the base substrate 100, and the removable protective layer 400 may be formed through step S311 and step S312.

In step S311, the surface of the electroplated metal layer 303 away from the base substrate 100 is micro-etched;

In step S312, the removable protective layer 400 is formed on the surface of the electroplated metal layer 303 away from the base substrate 100.

In step S311, a purpose of micro-etching is to remove an oxide layer on the surface of the electroplated metal layer 303 to form a rough surface of the electroplated metal layer 303, to facilitate for film formation. The micro-etching thickness directly affects a rate of the film formation, so it is very important to maintain a stable micro-etching thickness to form a stable film thickness. Generally, it is more appropriate to control the micro-etching thickness in a range of 1.0 μm-1.5 μm.

Before the micro-etching, steps such as oil removal and water washing may also be included to ensure cleanliness of the surface of the electroplated metal layer 303.

In step S312, the removable protective layer 400 is directly formed on the surface of the electroplated metal layer 303 away from the base substrate 100, specifically, the removable protective layer 400 may be film-formed on the whole surface. The removable protective layer 400 directly covers the surface of the electroplated metal layer 303.

In this embodiment, between step S310 and step S400, the method further includes:

step S310-1, forming a solder resist layer 500 on a surface of the removable protective layer 400 away from the base substrate 100, the solder resist layer 500 having a plurality of second openings, and an orthographic projection of the second openings on the base substrate 100 at least partially overlapping with an orthographic projection of the pads 305 on the base substrate 100.

The solder resist layer 500 is used to prevent soldering in a position of the electroplated metal layer 303 where it is not supposed to be soldered. The material of the solder resist layer 500 may be an organic material, which may display white oil or green oil commonly used in the art, and will not be specifically limited.

It should be noted that a decomposition temperature of the removable protective layer 400 is lower than a temperature at which the solder resist layer 500 is formed. For example, the temperature for forming the solder resist layer 500 generally does not exceed 250° C., and the decomposition temperature of the removable protective layer 400 generally should be higher than 250°° C., to ensure that the removable protective layer 400 may not be removed in a process of forming the solder resist layer 500.

As shown in FIG. 9, in another embodiment, after the solder resist layer 500 is formed on the surface of the electroplated metal layer 303 away from the base substrate 100, and the removable protective layer 400 is formed on a surface of the solder resist layer 500 away from the base substrate 100. In this embodiment, between step S250 and step S400, the method further includes:

step S250-1, forming a solder resist layer 500 on the surface of the electroplated metal layer 303 away from the base substrate 100, the solder resist layer 500 having a plurality of second openings, and the second openings exposing at least a partial region of the pads 305. In this embodiment, the solder resist layer 500 is directly formed on the surface of the electroplated metal layer 303 away from the base substrate 100. The solder resist layer 500 is also used to prevent soldering in a position of the electroplated metal layer 303 where it is not supposed to be soldered. The material of the solder resist layer 500 may be an organic material, which may display white oil or green oil commonly used in the art, and will not be specifically limited.

In this embodiment, step S310′ is used to form the removable protective layer 400.

In step S310′, the removable protective layer 400 is formed by a film forming process, and the removable protective layer 400 at least covers the surface of the electroplated metal layer 303 exposed by the solder resist layer 500.

In the above two embodiments, the removable protective layer 400 is directly formed on the surface of the electroplated metal layer 303, that is, the removable protective layer 400 is in direct contact with the surface of the electroplated metal layer 303; or the solder resist layer 500 is first directly formed on the surface of the electroplated metal layer 303, that is, the solder resist layer 500 is in direct contact with the surface of the electroplated metal layer 303 that is not supposed to be soldered. In any embodiments, there is no need to form an inorganic protective layer on the surface of the electroplated metal layer 303. Compared with the related art, a process of forming the inorganic protective layer may be directly omitted, and a process of patterning the inorganic protective layer may be further omitted, which can help to improve the production efficiency and reduce the production cost.

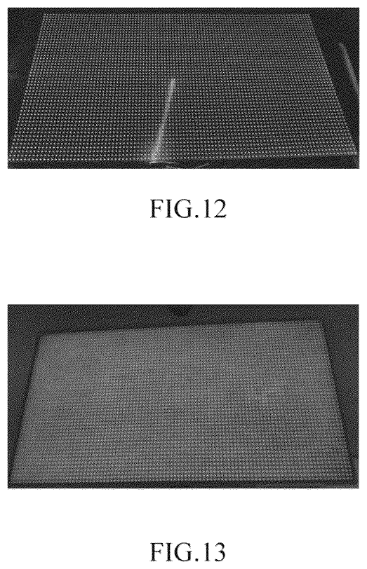

In the present disclosure, the above two embodiments can obtain a qualified array substrate, and specifically, as shown in FIG. 12 and FIG. 13, the LED 601 on the array substrate can be illuminated. FIG. 12 corresponds to an embodiment in which the removable protective layer 400 is formed before the solder resist layer 500 is formed, and FIG. 13 corresponds to an embodiment in which the solder resist layer 500 is formed before the removable protective layer 400 is formed.

As shown in FIG. 1, in step S400, the functional device is connected to the pads 305, and the removable protective layer 400 is decomposed and removed in this step.

The temperature in this step is generally higher, and the removable protective layer 400 may be decomposed and removed at a higher temperature. For example, a process temperature in this step is 270° C.-290° C., and at this temperature, the removable protective layer 400 may be decomposed and removed. In this way, the surface of the exposed clean electroplated metal layer 303 can be immediately combined with the molten solder in an extremely short time to form a firm solder joint.

The manufacturing method for the array substrate according to the present disclosure can improve the production efficiency and reduce the production cost in aspects of shortening the electroplating time and the etching time, reducing process steps, and the like. By adopting the array substrate formed by the manufacturing method, the thickness of the formed wirings 304 and the thickness of the pads 305 are relatively high, and hence in the steps of manufacturing and forming the array substrate, testing and reworking and the like, multiple reworking operations can be supported and completed, for example, replacing dead pixels (non-luminous LED light beads 601) for multiple times. This can improve the product yield and reduce the production cost.

As shown in FIG. 1, the present disclosure further provides an array substrate, which may be manufactured by the manufacturing method in any one of the above embodiments. The array substrate includes a base substrate 100, a plurality of wirings 304, a plurality of pads 305, and a functional device layer. The plurality of wirings 304 and the plurality of pads 305 are disposed on a side of the base substrate 100, and the plurality of wirings 304 and the plurality of pads 305 are disposed in a same layer. The functional device layer is disposed on a side of the plurality of wirings 304 and the plurality of pads 305 away from the base substrate 100, and the functional device layer is connected to the pads 305.

The functional device may include a flexible circuit board or drive chip 602 and a LED 601. The LED 601 may be an LED light bead 601, or may be a micro LED or a mini LED. The array substrate may include a plurality of light-emitting regions arranged in an array. Taking the LED 601 as an example, each light-emitting region may include a plurality of LEDs 601. For example, each light-emitting region of the array substrate has at least eight pads 305; every two pads 305 are connected to one LED 601, i.e., one of the two pads 305 is connected to one electrode of the LED 601, and the other of the two pads 305 is connected to the other electrode of the LED 601. Different LEDs 601 may be connected in series or in parallel with each other through the wiring 304 to form a light-emitting unit. Each light-emitting unit may be loaded with a common voltage or a drive voltage through different wirings 304, to drive the LEDs 601 to emit light.

The array substrate may further include a buffer layer 200 among the base substrate 100, the plurality of wirings 304, and the plurality of pads 305.

The present disclosure further provides a display apparatus including the array substrate according to any one of the embodiments of the present disclosure. The display apparatus may be a product or a component such as a mobile phone, a tablet computer, a television, a display, a notebook computer, a digital photo frame, a navigator, an electronic watch, and a smart bracelet.

It should be noted that although the steps involved in the method of the present disclosure are described in a particular order in the accompanying figures, this does not require or imply that the steps must be performed in the particular order, or all the illustrated steps must be performed to achieve the desired result. Additionally or alternatively, some steps may be omitted, or multiple steps may be combined into one step to be performed, and/or one step is decomposed into multiple steps to be performed, all of which should be regarded as a part of the present disclosure.

It should be understood that the present disclosure does not limit its application to the detailed structure and component arrangement as provided in the present specification. The present disclosure can have other embodiments and can be implemented in various ways. The foregoing variations and modifications fall within the scope of the present disclosure. It should be understood that the present disclosure may extend to all alternative combinations of two or more of separate features that are mentioned or apparent from the text and/or drawings. All of these different combinations constitute various alternative aspects of the present disclosure. The embodiments described herein illustrate the methods best known for implementing the present disclosure and will allow those skilled in the art to utilize the present disclosure.

What is claimed is:

1. A manufacturing method for an array substrate, comprising:
providing a base substrate;
forming a drive circuit layer on a side of the base substrate, the drive circuit layer comprising a plurality of wirings and a plurality of pads, and the plurality of wirings and the plurality of pads being disposed on a same layer;
forming a removable protective layer on a side of the drive circuit layer away from the base substrate, an orthographic projection of the removable protective layer on the base substrate at least partially overlapping with orthographic projections of the plurality of wirings and the plurality of pads on the base substrate; and
connecting a functional device to the pads, the removable protective layer being decomposed and removed in this step,
wherein a step of forming an inorganic protective layer and patterning the inorganic protective layer is not be included between a step of forming the drive circuit layer on the side of the base substrate and a step of forming the removable protective layer on the side of the drive circuit layer away from the base substrate.

2. The manufacturing method for the array substrate according to claim 1, wherein
forming the drive circuit layer on the side of the base substrate comprises:
forming a conductive seed layer on the side of the base substrate;
forming a removable pattern defining layer on a surface of the conductive seed layer away from the base substrate, the removable pattern defining layer being provided with a plurality of first openings, and the first openings exposing a part of the conductive seed layer;
forming an electroplated metal layer on the surface of the conductive seed layer in the first openings by an electroplating process, the electroplated metal layer comprising a plurality of growth wirings and a plurality of growth pads;
removing the removable pattern defining layer; and
removing a part of the conductive seed layer, which is not covered by the electroplated metal layer, to form a plurality of seed wirings and a plurality of seed pads, the seed wirings and the growth wirings in correspondence with the seed wirings forming the wirings, and the seed pads and the growth pads in correspondence with the seed pads forming the pads,
wherein forming the removable protective layer on the side of the drive circuit layer away from the base substrate comprises:
forming the removable protective layer on a side of the electroplated metal layer away from the base substrate.

3. The manufacturing method for the array substrate according to claim 2, wherein
forming the removable pattern defining layer on the surface of the conductive seed layer away from the base substrate comprises:
forming a photoresist material layer on the surface of the conductive seed layer away from the base substrate; and
exposing and developing the photoresist material layer to form the removable pattern defining layer.

4. The manufacturing method for the array substrate according to claim 3, wherein the photoresist material layer is formed by using a degradable photoresist material, and the degradable photoresist material is a material capable of being dissolved in a degradation solution after curing; and
removing the removable pattern defining layer comprises:
dissolving the removable pattern defining layer by using the degradation solution.

5. The manufacturing method for the array substrate according to claim 3, wherein the photoresist material layer is a positive photoresist material layer; and
an angle between a sidewall of each of the first openings and a plane where the electroplated metal layer is located is from 75° to 90°.

6. The manufacturing method for the array substrate according to claim 3, wherein the base substrate comprises a plurality of sub-electroplated regions arranged in an array, and each of the sub-electroplated regions comprises a first electroplated region and a second electroplated region;
forming the electroplated metal layer on the surface of the conductive seed layer in the first openings by the electroplating process comprises:
by the electroplating process, forming a first electroplated metal layer on the surface of the conductive seed layer in the first openings located in the first electroplated region, and forming a second electroplated metal layer on the surface of the conductive seed layer in the first openings located in the second electroplated region,
wherein the first electroplated metal layer comprises the plurality of growth wirings and the plurality of growth pads, the second electroplated metal layer comprises a virtual growth wiring, and the electroplated metal layer comprises the first electroplated metal layer and the second electroplated metal layer.

7. The manufacturing method for the array substrate according to claim 6, wherein the first electroplated region is located at a periphery of the second electroplated region.

8. The manufacturing method for the array substrate according to claim 2, wherein a ratio of an area of the electroplated metal layer to an area of the array substrate does not exceed ⅓.

9. The manufacturing method for the array substrate according to claim 2, wherein a thickness of the removable pattern defining layer is greater than a thickness of the electroplated metal layer; and
the thickness of the removable pattern defining layer is from 8 μm to 20 μm.

10. The manufacturing method for the array substrate according to claim 2, wherein forming the removable protective layer on the side of the electroplated metal layer away from the base substrate comprises:
micro-etching a surface of the electroplated metal layer away from the base substrate; and
forming the removable protective layer on the surface of the electroplated metal layer away from the base substrate.

11. The manufacturing method for the array substrate according to claim 10, wherein after forming the removable protective layer on the side of the electroplated metal layer away from the base substrate and before connecting the functional device to the pads, the manufacturing method further comprises:
forming a solder resist layer on a surface of the removable protective layer away from the base substrate, the solder resist layer having a plurality of second openings, and an orthographic projection of the second openings on the base substrate at least partially overlapping with an orthographic projection of the pads on the base substrate.

12. The manufacturing method for the array substrate according to claim 2, wherein after removing the part of the conductive seed layer, which is not covered by the electroplated metal layer, and before forming the removable protective layer on the side of the electroplated metal layer away from the base substrate, the manufacturing method further comprises:
forming a solder resist layer on a surface of the electroplated metal layer away from the base substrate, the solder resist layer having a plurality of second openings, and the second openings exposing at least a portion of the pads.

13. The manufacturing method for the array substrate according to claim 12, wherein forming the removable protective layer on the side of the electroplated metal layer away from the base substrate comprises:
forming the removable protective layer by a film forming process, the removable protective layer at least covering the surface of the electroplated metal layer exposed by the solder resist layer.

14. The manufacturing method for the array substrate according to claim 1, wherein the wiring and the pad have a thickness of 4 μm-18 μm.

15. An array substrate manufactured by the manufacturing method according to claim 1.

16. A display apparatus, comprising the array substrate according to claim 15.
